(19) United States
(12) Patent Application Publication
(10) Pub. No.: US 2017/0161141 A1
(43) Pub. Date: Jun. 8, 2017

(54) METHOD AND APPARATUS FOR CORRECTING DATA IN MULTIPLE ECC BLOCKS OF RAID MEMORY

(71) Applicant: SAMSUNG ELECTRONICS CO., LTD., Suwon-Si (KR)

(72) Inventors: YOAV SHERESHEVSKI, RAMAT GAN (IL); MOSHE TWITTO, RAMAT GAN (IL); JUN JIN KONG, YONGIN-SI (KR)

(21) Appl. No.: 14/956,726

(22) Filed: Dec. 2, 2015

(51) Int. Cl. G06F 11/10; H03M 13/15; G11C 29/52

(52) U.S. Cl. CPC G06F 11/1068; G11C 29/52; H03M 13/152; G06F 11/1004

(57) ABSTRACT

A method of correcting values errantly attributed to bits of error correction code (ECC) blocks during a read operation. The method includes, upon determining that an error exists in the j^{th} bit of one or more of the ECC blocks: 1) retrieving an estimate of the voltage value stored by the nonvolatile memory cell corresponding to the j^{th} bit of each of the ECC blocks having errant data; 2) identifying, among the voltage value estimates retrieved in operation (1), an ECC block whose corresponding voltage value estimate retrieved in operation (1) is closest to the voltage value of a decision boundary for determining whether to assign a bit value of “0” or “1” to the j^{th} bit of the ECC blocks; and 3) inverting the value of the j^{th} bit of the ECC block identified in operation (2).

### BACKGROUND

1. Technical Field

The present disclosure relates to improving the reliability of information encoded through block-level or outer error-correction code (ECC) schemes within NAND memory.

2. Description of the Related Art

In NAND flash memory, information is partitioned into data units (e.g., 2 KB) and each such data unit is encoded into an error correction code (ECC) block. A conventional use of a redundant array of independent disks (RAID) in flash memory consists of writing an extra parity block for every N ECC blocks. This extra block is constructed as the XOR of the N Blocks (bitwise).

Denote by Yₖ, k=1, N the k-th ECC block, and by Y_{N+1} the parity block, where Y_{N+1}=Y₁ ⊕Y₂ ⊕ . . . ⊕Y_{N}. The overall writing rate is reduced by 1/N+1 due to the parity block, but the added redundancy provides a lower frame error rate (FER).

The above-described RAID configuration employing the XOR operation for creating a parity block is just one example of RAID. Other RAID configurations exist that employ more sophisticated operations for creating a small ECC block. For example, a RAID configuration exists that adds two ECC blocks for each N ECC blocks and can correct two blocks that have too many errors (such that the ECC fails).

Any ECC has some failure rate. In NAND flash memory, for example, the required FER is about 1E-12. To mitigate a failure event, the validity of the data is checked using a cyclic redundancy check (CRC) code.

The main idea of RAID is that the data can be still reconstructed, even though the ECC decoder fails. This reconstruction can consume much more time than regular reading, but it happens only rarely. In order to reconstruct a failed ECC block, all N other blocks in the RAID code should be read and ECC-decoded. Then, if all other N blocks are free of errors (after regular ECC decoding), the bitwise XOR of those N codewords gives the correct codeword.

If, on the other hand, there are one or more erroneous codewords in the other N ECC blocks in the RAID block, conventional methods fails to reconstruct the failed ECC block.

### SUMMARY

According to an embodiment of the disclosure, there is provided a method, executed by a memory controller, of correcting a value errantly attributed to a bit of an error correction code (ECC) block during a read operation of a nonvolatile memory. The method includes: a) identifying, among ECC blocks, errant ECC blocks that each has an errant value attributed to a bit of the ECC block; b) determining whether an error exists in the j^{th} bit of one or more of the ECC blocks; and c) performing operations (c1) through (c3) upon determining that the error exists in the j^{th} bit of one or more of the ECC blocks: c1) retrieving an estimate of the voltage value stored by the nonvolatile memory cell corresponding to the j^{th} bit of each of the errant ECC blocks; c2) identifying, among the voltage value estimates retrieved in operation (c1), an ECC block whose corresponding voltage value estimate retrieved in operation (c1) is closest to the voltage value of a decision boundary for determining whether to assign a bit value of “0” or “1” to the j^{th} bit of the ECC blocks; and c3) inverting the value of the j^{th} bit of the ECC block identified in operation (c2).

In an embodiment, the method may further include: d) performing operations (b) and (c) for every value 1≦j≦m, where m is the number of bits within each of the ECC blocks.

In an embodiment, the method may further include repeating operations (a) through (d) until fewer than two errant blocks are identified in operation (a) or the number of errant blocks identified in operation (a) does not decrease in successive repetitions of operations (a) through (d).

In an embodiment, a cyclic redundancy check (CRC) code is applied to each ECC block to identify, among the ECC blocks, the errant ECC blocks that have an errant value attributed to a bit of the ECC block.

In an embodiment, the method may further include performing Bose-Chaudhuri-Hocquenghem (BCH) decoding on each ECC block prior to applying the CRC code to each ECC block.

In an embodiment, the method may further include: d) performing operations (b) and (c) for every value 1≦j≦m, where m is the number of bits within each of the ECC blocks.

In an embodiment, the method may further include repeating operations (a) through (d) until fewer than two errant blocks are identified in operation (a) or the number of errant blocks identified in operation (a) does not decrease in successive repetitions of operations (a) through (d).

In an embodiment, the ECC blocks comprise Y₁ . . . Y_{N} ECC blocks of data encoded with a Bose-Chaudhuri-Hocquenghem (BCH) code and a Y_{N+1} parity block in which Y_{N+1}=Y₁ ⊕Y₂ ⊕ . . . ⊕Y_{N}, where ⊕ is an exclusive-OR (XOR) operator, and N is an integer greater than 1.

According to another embodiment of the disclosure, there is provided a memory device that includes: a nonvolatile memory; and a memory controller that: a) attributes, for each of multiple error correction code (ECC) blocks, values to bits of the ECC block during a read operation of the nonvolatile memory; b) identifies, among ECC blocks, errant ECC blocks that each has an errant value attributed to a bit of the ECC block; c) determines whether an error exists in the j^{th} bit of one or more of the ECC blocks; and d) performs operations (d1) through (d3) upon determining that the error exists in the j^{th} bit of one or more of the ECC blocks: d1) retrieve an estimate of the voltage value stored by the nonvolatile memory cell corresponding to the j^{th} bit of each of the errant ECC blocks; d2) identify, among the voltage value estimates retrieved in operation (d1), an ECC block whose corresponding voltage value estimate retrieved in operation (d1) is closest to the voltage value of a decision boundary for determining whether to assign a bit value of “0” or “1” to the j^{th} bit of the ECC blocks; and d3) invert the value of the j^{th} bit of the ECC block identified in operation (d2).

In an embodiment, the memory controller further: e) performs operations (c) and (d) for every value 1≦j≦m, where m is the number of bits within each of the ECC blocks.

In an embodiment, the memory controller further repeats operations (b) through (e) until fewer than two errant blocks are identified in operation (b) or the number of errant blocks identified in operation (b) does not decrease in successive repetitions of operations (b) through (e).

In an embodiment, the memory controller applies a cyclic redundancy check (CRC) code to each ECC block to identify, among the ECC blocks, the errant ECC blocks that have an errant value attributed to a bit of the ECC block.

In an embodiment, the memory controller performs Bose-Chaudhuri-Hocquenghem (BCH) decoding on each ECC block prior to applying the CRC code to each ECC block.

In an embodiment, the ECC blocks comprise Y₁ . . . Y_{N} ECC blocks of data encoded with a Bose-Chaudhuri-Hocquenghem (BCH) code and a Y_{N+1} parity block in which Y_{N+1}=Y₁ ⊕Y₂ ⊕ . . . ⊕Y_{N}, where ⊕ is an exclusive-OR (XOR) operator, and N is an integer greater than 1.

According to another embodiment of the disclosure, there is provided a non-transitory computer readable medium storing instructions that when executed by a processor cause the processor to execute a method of correcting a value errantly attributed to a bit of an error correction code (ECC) block during a read operation of a nonvolatile memory. The method includes: a) identifying, among ECC blocks, errant ECC blocks that each has an errant value attributed to a bit of the ECC block; b) determining whether an error exists in the j^{th} bit of one or more of the ECC blocks; and c) performing operations (c1) through (c3) upon determining that an error exists in the j^{th} bit of one or more of the ECC blocks: c1) retrieving an estimate of the voltage value stored by the nonvolatile memory cell corresponding to the j^{th} bit of each of the errant ECC blocks; c2) identifying, among the voltage value estimates retrieved in operation (c1), an ECC block whose corresponding voltage value estimate retrieved in operation (c1) is closest to the voltage value of a decision boundary for determining whether to assign a bit value of “0” or “1” to the j^{th} bit of the ECC blocks; and c3) inverting the value of the j^{th} bit of the ECC block identified in operation (c2).

In an embodiment, the method further includes: d) performing operations (b) and (c) for every value 1≦j≦m, where m is the number of bits within each of the ECC blocks.

In an embodiment, the method further includes repeating operations (a) through (d) until fewer than two errant blocks are identified in operation (a) or the number of errant blocks identified in operation (a) does not decrease in successive repetitions of operations (a) through (d).

In an embodiment, the method further includes applying a cyclic redundancy check (CRC) code to each ECC block to identify, among the ECC blocks, the errant ECC blocks that have an errant value attributed to a bit of the ECC block.

In an embodiment, the method further includes performing Bose-Chaudhuri-Hocquenghem (BCH) decoding on each ECC block prior to applying the CRC code to each ECC block.

In an embodiment, the ECC blocks comprise Y Y_{N} ECC blocks of data encoded with a Bose-Chaudhuri-Hocquenghem (BCH) code and a Y_{N+1} parity block in which Y_{N+1}=Y₁ ⊕Y₂ ⊕ . . . ⊕Y_{N}, where ⊕ is an exclusive-OR (XOR) operator, and N is an integer greater than 1.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 illustrates a memory device, according to an embodiment of the disclosure;

FIG. 2 illustrates a method for correcting errant data within error correction code (ECC) blocks of a redundant array of independent disks (RAID);

FIG. 3 illustrates the possible improvement for N=64 ECC blocks and 1 KB code words used with a BCH hard decision decoder when applying an embodiment of the disclosure; and

FIG. 4 illustrates the possible improvement for N=64 ECC blocks and 2 KB code words with a BCH hard decision decoder when applying an embodiment of the disclosure.

### DETAILED DESCRIPTION OF EMBODIMENTS

The advantages and features of the present disclosure and methods of achieving them will be apparent from the following example embodiments that will be described in more detail with reference to the accompanying drawings. It should be noted, however, that the present disclosure is not limited to the following example embodiments, and may be implemented in various forms. Accordingly, the example embodiments are provided only to disclose the present disclosure and let those skilled in the art know the concept of the present disclosure.

The terms used in the present disclosure are for the purpose of describing particular embodiments only and are not intended to be limiting of the present disclosure. As used in the specification, the singular forms “a”, “an” and “the” are intended to include the plural forms as well, unless the context clearly indicates otherwise. It will be further understood that the terms “comprises” and/or “comprising”, when used in the present disclosure, specify the presence of stated features, integers, steps, operations, elements, and/or components, but do not preclude the presence or addition of one or more other features, integers, steps, operations, elements, components, and/or groups thereof.

Hereinafter, example embodiments of the present disclosure will now be described more fully with reference to accompanying drawings.

In an embodiment of the disclosure, soft decision (SD) data is used instead of or in addition to conventional hard decision (HD) data. SD provides a reliability value for every bit of a code block in addition to its HD value.

As discussed above, in connection with NAND flash memory, information is partitioned into data units (e.g., 2 KB) and each such data unit is encoded into an error correction code (ECC) block. The encoding is achieved by writing an extra parity block for every N ECC blocks. This extra block is constructed as the XOR of the N Blocks (bitwise). For example, denote by Yₖ, k=1, N, the k-th ECC block, and by Y_{N+1} the parity block, where Y_{N+1}=Y₁ ⊕Y₂ ⊕ . . . ⊕Y_{N}.

An embodiment of the disclosure operates as follows. When an ECC block fails, such as in error block Yₖ, all N other ECC blocks Yₙ {1≦n≦N+1; n≠k} are read. Each code block reading is marked as fail/success (group F/S respectively), and the code blocks are assigned to one of two groups based upon whether the error block was read successfully. The group of successfully-read blocks is expressed as {nεS|Yₙ}. And the group of blocks that failed to be read properly is expressed as {nεF|Yₙ}. The XOR of all code blocks in group S is expressed by the equation:

Z=Σ_{nεs}Yₙ(mod 2).

Soft data SD data is produced for error block Yₖ and the group of blocks Yᵢ{iεF} that failed to be read properly. The soft data for the group of blocks Yᵢ{iεF} that failed to be read properly is denoted by Rₗ, l=1, 2, . . . , |F|+1 (the plus 1 is because Yₖ soft data is one of the Rₗ, l=1, 2, . . . . Alternatively, group F may be defined to contain Yₖ and the rest remain the same).

Define G(Y)=2Y−1 (bit to symbol mapping for bi-phase shift keying (BPS K); Y={0, 1}→G(Y)={−1, 1}), and let denote the j^{th} noise vector corresponding to the j^{th} ECC block of group F(j=1, . . . |F|+1). Then, we have the following relations:

R₁=G(Yₖ)+η₁,R₂=G(Y_{F{1}})+η₂, . . . ,R_{|F|+1}=G(Y_{F{|F|+1}})+η_{|F|+1}

Yₖ⊕Y_{F{1}}⊕Y_{F{2}}⊕ . . . Y_{F{|F|+1}}=Z.

Reconstructing Yₖ in an optimal manner is the desired outcome. There are many ways to perform this reconstruction. The manner of performing the reconstruction may depend on the read resolution (i.e., number of block reads), the number of blocks in the group of blocks that failed to be read properly (i.e., the number of blocks in the fails of group F), and the algorithmic computation complexity.

It can be shown that performance depends on the number of fails in the array, but does not depend on whether the fail happens on the extra XOR block (Y_{N+1}) or in any other block in the array. Reconstruction can be improved in a hard decision decoder, such as a Bose-Chaudhuri-Hocquenghem (BCH) decoder, or in a soft decision decoder, such as a low-density parity-check (LDPC) decoder.

In the case of a hard decision decoder, Z and R₁ are used to reduce the number of errors at the decoder input. Some intuition can be gained by the following example.

Say that while reading Y₁ there is a reading failure. Reading Y₂, Y₃, . . . , Y_{N+1} succeeds, except Y₂ which also experiences a reading failure. It becomes desirable to find R₁, R₂ and Z as: Z=Y₃ ⊕Y₄ ⊕ . . . ⊕Y_{N} ⊕Y_{N+1}. Define:

\tilde{Y}ᵢ≡(2Yᵢ−1)ε{−1,1}∀i;\tilde{Z}≡(2Z−1)ε{−1,1}.

Then:

Y₁⊕Y₂=Z [symbol] \tilde{Y}₂=−\tilde{Y}₁·\tilde{Z}

R₁=G(Y₁)+η₁=\tilde{Y}₁+η₁ [symbol] R₁=\tilde{Y}₁+η₁

R₂=G(Y₂)+η₂=\tilde{Y}₂+η₂=−\tilde{Y}₁·\tilde{Z}+η₂ [symbol] \tilde{R}₂=\tilde{Y}₁+\tilde{η}₂, where \tilde{Z}·\tilde{Z}=1,\tilde{R}₂=−\tilde{Z}·R₂,\tilde{Y}₁=G(Y₁),\tilde{Y}₂=G(Y₂), and \tilde{η}₂=−\tilde{Z}·η₂.

Using (R₁+\tilde{R}₂)/2 as the input to the slicer: \tilde{Y}′₁=sign ((R₁+\tilde{R}₂)/2), the noise power is reduced by a factor of 2.

As another example, suppose a reading failure occurred for memory block Y₁, readings of blocks Y₂ and Y₃ also failed, but readings of blocks Y₄ through Y_{N+1} succeeded. R₁, R₂, R₃, and Z may be found as follows:

Z=Y₄⊕Y₅⊕ . . . ⊕Y_{N}⊕Y_{N+1}.

R₁=\tilde{Y}₁+η₁

R₂=\tilde{Y}₂+η₂

R₃=\tilde{Y}₃+η₃

Y₁⊕Y₂⊕Y₃=Z [symbol] \tilde{Y}₁·\tilde{Y}₂·\tilde{Y}₃=\tilde{Z},

\tilde{Y}ᵢ≡(2Yᵢ−1)ε{−1,1}; and \tilde{Z}≡(2Z−1)ε{−1,1}

Using: \tilde{Y}₃=\tilde{Y}₁·\tilde{Y}₂·\tilde{Z}; and \tilde{Z}·\tilde{Z}=1, leads to:

\tilde{Z}·R₃=\tilde{Y}₁·\tilde{Y}₂+\tilde{Z}·η₃ [symbol] \tilde{R}₃=\tilde{Y}₁·\tilde{Y}₂+\tilde{η}₃,

where \tilde{R}₃=\tilde{Z}·R₃ and \tilde{η}₃−\tilde{Z}·η₃.

From the above, the following three equations are obtained:

R₁=\tilde{Y}₁+η₁,

R₂=\tilde{Y}₂+η₂, and

\tilde{R}₃=\tilde{Y}₁·\tilde{Y}₂+\tilde{η}₃.

If single-level cells (SLCs) are written with levels centered around {−1, 1} and 0 Volts is the decision border (i.e. the sign of the read indicates if it is −1 or 1). When the read voltage is closer to 0 Volts the chance of an error increases.

A simple, yet effective, solution can be:

if

$$\overbrace{( sign ( {R}_{1} ) \cdot sign ( {R}_{2} ) \neq sign ( {\tilde{R}}_{3} ) )}^{condition 1} \& \overbrace{( \vert {R}_{1} \vert < \vert {R}_{2} \vert )}^{condition 2} \& \overbrace{( \vert {R}_{1} \vert < \vert {R}_{3} \vert )}^{condition 3}$$

then \tilde{Y}₁=−sign(R₁),

else \tilde{Y}₁=sign(R₁), where the sign(x) returns a value of −1 for values of x less than zero and +1 for all values of x greater than zero.

The first condition indicates that the third equation does not agree with the first two, which indicates there is at least one mistake among R₁, R₂, and R₃. The second and third conditions verify that the mistake is most probably at the Y₁ block; therefore its original value is flipped (i.e., inverted).

To better understand how the mathematical discussion above may be put into practice, suppose a RAID of 10 blocks exists, with each block having 10000 bits. The bits in each block are BCH coded so that BCH decoding corrects up to “m” errors within the block. In this example, let m=60 bit errors. When data is written to the RAID, 9 blocks (90000 bits total) of new BCH-encoded information is collected and a 10^{th} block is produced as the XOR values of the 9 blocks (bitwise). This 10^{th} block doesn't carry any new information and is totally determined by the first 9 blocks. The i^{th} bit of the 10^{th} block is represented as:

x₁₀ⁱ=x₁ⁱ⊕x₂ⁱ⊕x₃ⁱ⊕x₄ⁱ⊕x₅ⁱ⊕x₆ⁱ⊕x₇ⁱ⊕x₈ⁱ⊕x₉ⁱ, which is equivalent to:

0=x₁ⁱ⊕x₂ⁱ⊕x₃ⁱ⊕x₄ⁱ⊕x₅ⁱ⊕x₆ⁱ⊕x₇ⁱ⊕x₈ⁱ⊕x₉ⁱ⊕x₁₀ⁱ, where the subscript represent the block number and the superscript is the bit location in the block.

Suppose the 10 blocks of data are stored in a nonvolatile memory for some time and subsequently accessed. The access (i.e., reading) is done only in the border between levels so as to obtain an estimate of each bit value for all blocks. A BCH decoding operation is performed on each of the 10 blocks. Usually there are less than 61 read errors per 10,000 bit block, but sometimes not. If less than 61 read errors exist in the block, then the BCH decoding operation corrects all of them. Otherwise, additional error correction is required to recover the information of the block.

A CRC operation executed on each block gives an indication of whether the data of the block was entirely corrected by the BCH decoding operation. For this example, suppose 62 errors exist in block 1, 63 errors exist in blocks 2 and 3, and less than 60 errors exist in blocks 4, 5, 6, 7, 8, 9, and 10. The BCH decoding operation corrects all the errors of blocks 4 through 10, and the CRC applied to each of these blocks indicates that there are no errors in these blocks. The CRC operation applied to blocks 1-3 indicates that each of these blocks contains errors that are uncorrectable by the BCH decoding operation.

To correct the bit errors in blocks 1-3, determine whether:

0=\acute{x}₁ⁱ⊕\acute{x}₂ⁱ⊕\acute{x}₃ⁱ⊕x₄ⁱ⊕x₅ⁱ⊕x₆ⁱ⊕x₇ⁱ⊕x₈ⁱ⊕x₉ⁱ⊕x₁₀ⁱ,

where \acute{x}, in blocks 1-3 indicates that the assigned bit value is an estimate and, therefore, can be mistaken. The bit values of blocks 4-10 are known to be correct based upon the CRC operation. Recall from above, that the access (i.e., reading) is done only in the border between levels so as to obtain an estimate of each bit value for all blocks. For example if cells levels are ideally at 3 volt to represent “0” and 4 volt to represent “1,” the estimation is “0” if the voltage is below 3.5 and “1” if its above (when 3.5 [v] is the estimation border: the border can also be asymmetrically assigned).

If 0=\acute{x}₁ⁱ⊕\acute{x}₂ⁱ⊕\acute{x}₃ⁱ⊕x₄ⁱ⊕x₅ⁱ⊕x₆ⁱ⊕x₇ⁱ⊕x₈ⁱ⊕x₉ⁱ⊕x₁₀ⁱ, there are either no errors, 2 errors, or another even number of errors. Because the probability of two or more errors is much lower than the probability of no errors, an equivalency in the equation is assumed to provide an indication of no errors. For an indication of no errors or two errors, the error-correction scheme assumes no errors and consideration is given to the i^{th}+1 bit.

If 0≠\acute{x}₁ⁱ⊕\acute{x}₂ⁱ⊕\acute{x}₃ⁱ⊕x₄ⁱ⊕x₅ⁱ⊕x₆ⁱ⊕x₇ⁱ⊕x₈ⁱ⊕x₉ⁱ⊕x₁₀ⁱ, then there is either 1 error among \acute{x}₁ⁱ, \acute{x}₂ⁱ, \acute{x}₃ⁱ or three errors. Because the likelihood of three errors in small, we assume 1 error exists. To identify the single bit error, the soft information values of the three prospectively errant bits are considered. The soft information values are the read voltage of each bit (i.e., an estimate of the voltage stored by the nonvolatile memory cell corresponding to the bit). Suppose the soft value (i.e., cell voltage) of the three bits \acute{x}₁ⁱ, \acute{x}₂ⁱ, \acute{x}₃ⁱ is estimated to be 3.9 V, 3.2 V, 4.3 V, respectively, and the levels are centered at 3 volt (say “0”) and 4 volt (say “1”) and 3.5 V is the read voltage (border). According to the error-correction scheme, the hard value (i.e., 0 or 1) corresponding to the soft information value closest to the decision border between 3 and 4 volts will be changed to its opposite value. Because voltage 3.2 V of bit \acute{x}₂ⁱ, among bits \acute{x}₁ⁱ, \acute{x}₂ⁱ, \acute{x}₃ⁱ, is the closest to the decision border of 3.5 V, the hard value of bit \acute{x}₂ⁱ is changed to its opposite value. For example, if the bit value of bit \acute{x}₂ⁱ was originally estimated to be “0,” its value is changed to “1.” And if the bit value of bit \acute{x}₂ⁱ was originally estimated to be “1,” its value is changed to “0.” Bits \acute{x}₁ⁱ and \acute{x}₃ⁱ remain unchanged. In this example, the bit value of bit \acute{x}₂ⁱ was originally estimated to be “0” and is changed to “1.” These operations are performed for each value of bit index i, which in this example is 1≦i≦10,000.

Thereafter, the BCH decoding operation is performed on each of the blocks previously identified, by the last-performed CRC operation, as having errors. BCH decoding need not be executed on the blocks previously identified as having no errors, because these blocks were properly decoded. Then, the CRC operation is performed on the blocks that were most recently BCH decoded.

For the purpose of this example, assume that after the above-described operations have been performed on the i^{th} bit and 61, 61, and 59 errors remain in the first three blocks, respectively, before the BCH decoding and CRC operations are repeated. Usually, the number of remaining errors will be much less than 60 errors per block (after this procedure), but this example will assume error numbers of 61, 61, and 59. After performing the above-described XOR and bit changing operations, as necessary, for each of the 10,000 bit positions, the BCH decoding and CRC operations are performed again on the blocks that did not previously pass the CRC operation. In this example, all of the 59 errors in memory block 3 are corrected by the BCH decoding but memory blocks 1 and 2 contain too many errors to be corrected by the BCH decoding.

The above-described XOR and bit changing operations can be repeated for each of the 10,000 bit positions using the equation 0=\acute{x}₁ⁱ⊕\acute{x}₂ⁱ⊕x₃ⁱ⊕x₄ⁱ⊕x₅ⁱ⊕x₆ⁱ⊕x₇ⁱ⊕x₈ⁱ⊕x₉ⁱ⊕x₁₀ⁱ. This means that there won't be any more bits from block 3 that will be flipped or suspected as errors, only from blocks 1 and 2. Now, there will be more errors corrected from block 1 and 2 and the number of errors in those blocks will decrease. The above scheme is repeated until all blocks are corrected.

When the ECC is a soft-in soft-out (SISO) decoder such as LDPC, the parity block is used in a different manner. The parity block is not used to reduce the number of HD errors at the decoder input, as explained above, but instead the parity is used to improve the soft log likelihood ratios (LLRs) at the soft decoder input.

Improving the LLR's at the soft decoder (such as LDPC) can be done in many ways. Denote the LLR's at the decoder output as LLRₖⁱ where k is the Block number in the Raid array (k=0, 1 . . . , N Raid blocks), and i is the bit index in that block.

If a block was successfully read without error (e.g. CRC confirm no errors) then all its LLR's should be set to ±∞ (or ±“large” value) where the sign corresponds to the correct bit value (decoded bit 0→−∞ and 1→+∞).

The optimal LLR output using the parity information can be formulated as follows:

LLRoutₖⁱ=2·tan h⁻¹(Π_{j=1;j≠k}^{N}LLRⱼⁱ/2)

Then the soft decoder can decode again the LLR output (after the above equation inserts the parity block information) and the above equation can be implemented again on the soft decoder output. This iterative process stops when all bits are decoded correctly.

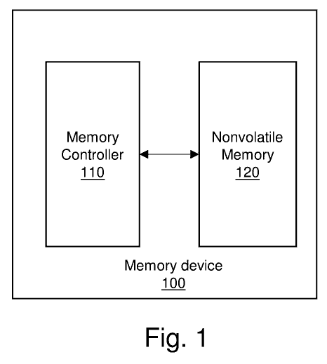

FIG. 1 illustrates a memory device according to an embodiment of the disclosure. Memory device 100 includes a memory controller 110 and a nonvolatile memory 120. Nonvolatile memory 120 may include a RAID, as described previously. Memory device 100 may include other components, such as address decoders, one or more input/output data buffers, a voltage generator, a random access memory (RAM), a power source, etc., but such components are not illustrated or described further as their functionality is unimportant to the subject matter of the disclosure. Memory controller 110 receives data from a host (not illustrated) for storage in nonvolatile memory 120 and reads data stored by nonvolatile memory 120 for conveyance to the host upon request by the host. Nonvolatile memory 120 may be a NAND memory or NAND flash memory. Memory controller 110 controls the operations for storing data into nonvolatile memory 120 and retrieving data from nonvolatile memory 120.

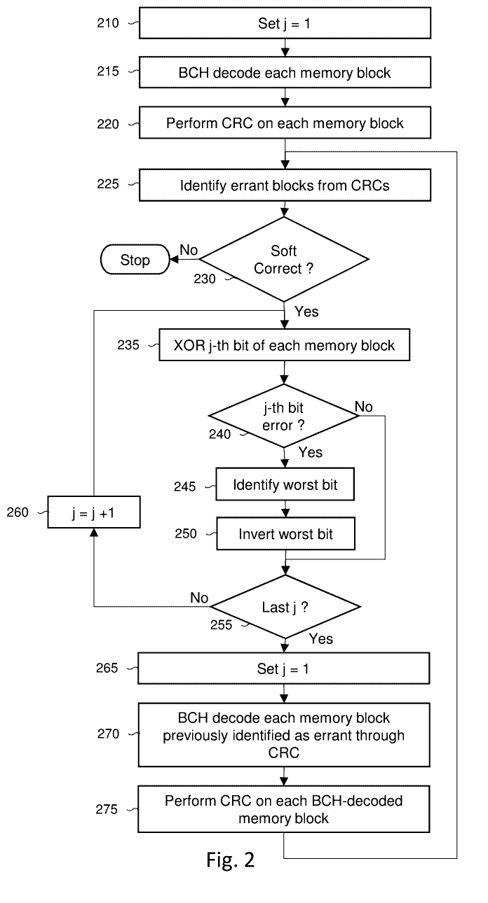

FIG. 2 illustrates a method for correcting errant data within an error correction code (ECC) block of data, in accordance with an embodiment of the disclosure. The method may be executed by memory controller 110.

For the purpose of explaining this embodiment, assume nonvolatile memory 120 stores Y₁ . . . Y_{N} ECC blocks of data and a Y_{N+1} parity block, as described previously. Memory controller 110 sets 210 a bit index “j” to a value of 1. Memory controller 110 applies 215 BCH decoding to each of the N+1 ECC blocks individually to correct all errors within the block up to the maximum number the BCH decoding can correct. Memory controller 110 applies 220 a CRC algorithm to each of the N+1 BCH-decoded ECC blocks to determine whether the block contains errors that were unable to be corrected by the BCH decoding. Memory controller 110 identifies 225 the blocks containing errors, as determined from the application 220, 275 of the CRC algorithm, as errant blocks.

Memory controller 110 determines 230 whether to apply a soft-decision error-correction scheme based upon several considerations. For example, if none of the ECC blocks are identified as having an error in operation 220, the memory controller 110 terminates the method illustrated by FIG. 2, as further error correction is unnecessary. If errors exist within only one of the ECC blocks, again memory controller may terminate the method of FIG. 2, as the errors within the one errant block may be corrected through an XOR operation applied to the N ECC blocks having no errors to identify the correct bit values for the one errant block. Also, if the soft-decision error-correction scheme has corrected all of the errors in each of the blocks that it can and the BCH decoding cannot produce at least N blocks of data having no bit errors, then memory controller 110 may terminate the method illustrated by FIG. 2. For example, if the same group of ECC blocks are determined 225 to have errant bits by the BCH decoding operation 215 executed in two separate loops through operations 225 through 275, then memory controller 110 may determine that further improvement of the errant data is unlikely and terminate the method illustrated by FIG. 2. Otherwise, memory controller 110 determines 230 to execute or continue executing, if execution has already begun, the soft-decision error-correction scheme.

Memory controller 110 performs 235 an XOR of the j^{th} bit of the N+1 ECC blocks. If the XOR operation 235 produces a value of zero, then no errors likely exist for the j^{th} bit of each of the N+1 ECC blocks. If the XOR operation 235 produces a value of one, then at least one error exists in the j^{th} bit of one or more of the N+1 ECC blocks.

Memory controller 110 determines 240 whether the XOR operation 235 indicates the presence of at least one errant bit among the j^{th} bits of the N+1 ECC blocks. If no errant bit is determined 240 to exist, then memory controller 110 proceeds to operation 255.

If an errant bit is determined 240 to exist, then memory controller 110 retrieves estimates of the voltage values stored by the memory cells corresponding to the j^{th} bit of each of the ECC blocks identified in operation 225 as having errant data. Among these retrieved voltage values, memory controller 110 identifies 245 the corresponding ECC block having a particular voltage value closest to the voltage value of the hard decision boundary for assigning a bit value of “0” or “1” to the j^{th} bit of the ECC block. For the identified 245 ECC block, memory controller 110 inverts 250 the bit value of the j^{th} bit.

Thereafter, memory controller 110 determines 255 whether the soft-decision error-correction scheme has been executed on every bit of the ECC blocks. If not, memory controller 110 increments 260 the value of bit index j and repeats the soft-decision error-correction scheme defined by operations 235 through 255 for the next value of j, which identifies a particular bit of the ECC blocks. Memory controller 110 repeats operations 235 through 260 until the soft-decision error-correction scheme has been executed on every bit of the ECC blocks. Although FIG. 2 and the discussion above indicate that the values of the bit index “j” are assigned from lowest to highest, such values may be assigned in any order.

After memory controller 110 determines 255 that operations 235 through 255 have been executed on every bit of the ECC blocks, memory controller 110 resets 265 the value of the bit index j to 1. Memory controller 110 applies 270 BCH decoding individually to each of the ECC blocks last identified 225 as being errant blocks, based upon the application 225, 275 of the CRC algorithm. The BCH decoding corrects all errors within each block, up to the maximum number the BCH decoding can correct. Memory controller 110 applies 275 the CRC algorithm to each of the blocks that were BCH-decoded in operation 270 to determine whether the block contains errors that were unable to be corrected by the BCH decoding.

Thereafter, memory controller 110 begins another loop through some or all of operations 225 through 275. Memory controller 110 may repeat such loops through some or all of operations 215 through 275 until one of the conditions identified above with respect to operation 230 occurs for terminating the method.

The method illustrated by FIG. 2 may be executed by a computer processor executing instructions read from a nonvolatile computer readable medium. The computer processor may be memory controller 110.

Other hard decision decoders may be substituted for the BCH decoder described in the exemplary embodiments of the disclosure. Similarly, a soft decision decoder, such as a low-density parity-check (LDPC) decoder, may be substituted for the BCH decoder described in the exemplary embodiments of the disclosure.

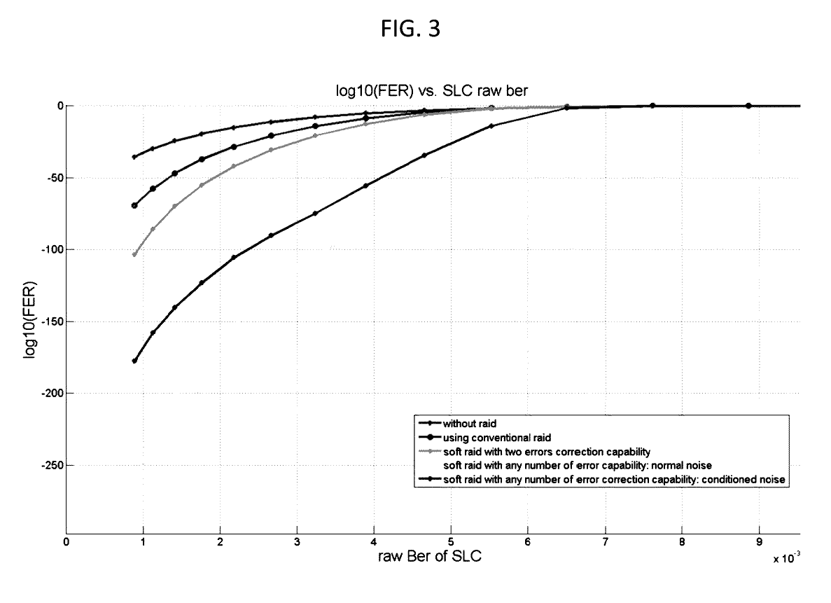

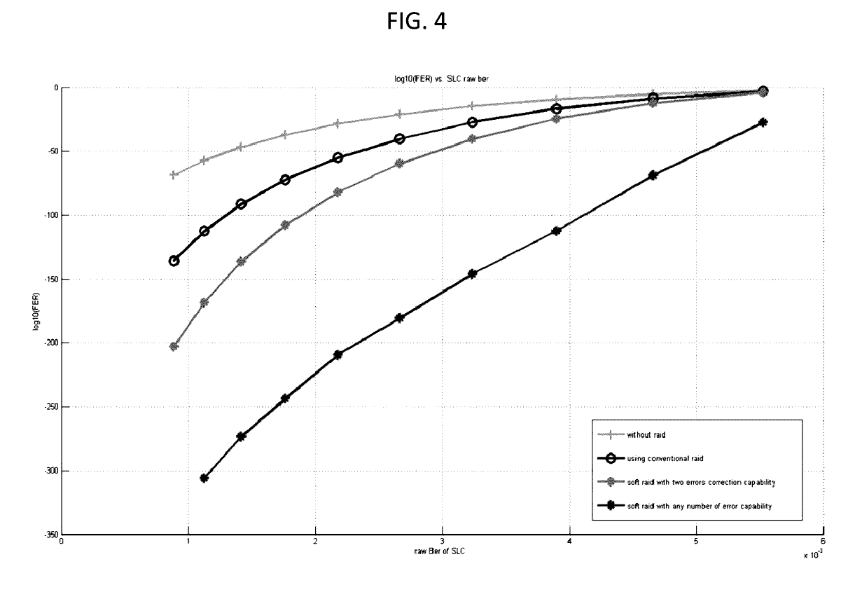

FIG. 3 illustrates the possible improvement for N=64 ECC blocks and 1 KB code words used with a BCH hard decision decoder. FIG. 4 illustrates the possible improvement for N=64 ECC blocks and 2 KB code words with a BCH hard decision decoder. Other block sizes and code word sizes may be used, as well.

A configuration illustrated in each conceptual diagram should be understood just from a conceptual point of view. Shape, structure, and size of each component illustrated in each conceptual diagram are exaggerated or downsized for understanding of the present disclosure. An actually implemented configuration may have a physical shape different from a configuration of each conceptual diagram. The present disclosure is not limited to a physical shape or size illustrated in each conceptual diagram.

The device configuration illustrated in each block diagram is provided to help convey an understanding of the present disclosure. Each block may include smaller blocks according to functions. Alternatively, a plurality of blocks may form a larger block according to a function. That is, the present disclosure is not limited to the components illustrated in each block diagram.

The operations illustrated in the drawings are illustrative of one or more embodiments of the disclosure, but are not limited to the sequence illustrated. Some operations may be omitted and additional operations may be included in embodiments of the disclosure. Also, the sequence of the operations may be changed and some operations may be performed either simultaneously or in sequence.

While the present disclosure has been particularly shown and described with reference to example embodiments thereof, the present disclosure is not limited to the above-described example embodiments. It will be understood by those of ordinary skill in the art that various changes and variations in form and details may be made therein without departing from the spirit and scope of the present disclosure as defined by the following claims.

What is claimed is:

1. A method, executed by a memory controller, of correcting a value errantly attributed to a bit of an error correction code (ECC) block during a read operation of a nonvolatile memory, the method comprising:
a) identifying, among ECC blocks, errant ECC blocks that each has an errant value attributed to a bit of the ECC block;
b) determining whether an error exists in the j^{th} bit of one or more of the ECC blocks; and
c) performing operations (c1) through (c3) upon determining that the error exists in the j^{th} bit of one or more of the ECC blocks:
c1) retrieving an estimate of the voltage value stored by the nonvolatile memory cell corresponding to the j^{th} bit of each of the errant ECC blocks;
c2) identifying, among the voltage value estimates retrieved in operation (c1), an ECC block whose corresponding voltage value estimate retrieved in operation (c1) is closest to the voltage value of a decision boundary for determining whether to assign a bit value of “0” or “1” to the j^{th} bit of the ECC blocks; and
c3) inverting the value of the j^{th} bit of the ECC block identified in operation (c2).

2. The method of claim 1, further comprising:
d) performing operations (b) and (c) for every value 1≦j≦m, where m is the number of bits within each of the ECC blocks.

3. The method of claim 3, further comprising repeating operations (a) through (d) until fewer than two errant blocks are identified in operation (a) or the number of errant blocks identified in operation (a) does not decrease in successive repetitions of operations (a) through (d).

4. The method of claim 1, wherein a cyclic redundancy check (CRC) code is applied to each ECC block to identify, among the ECC blocks, the errant ECC blocks that have an errant value attributed to a bit of the ECC block.

5. The method of claim 4, further comprising performing Bose-Chaudhuri-Hocquenghem (BCH) decoding on each ECC block prior to applying the CRC code to each ECC block.

6. The method of claim 5, further comprising:
d) performing operations (b) and (c) for every value 1≦j≦m, where m is the number of bits within each of the ECC blocks.

7. The method of claim 6, further comprising repeating operations (a) through (d) until fewer than two errant blocks are identified in operation (a) or the number of errant blocks identified in operation (a) does not decrease in successive repetitions of operations (a) through (d).

8. The method of claim 1, wherein:
the ECC blocks comprise Y₁ . . . Y_{N} ECC blocks of data encoded with a Bose-Chaudhuri-Hocquenghem (BCH) code and a Y_{N+1} parity block in which Y_{N+1}=Y₁ ⊕Y₂ ⊕ . . . ⊕Y_{N}, where ⊕ is an exclusive-OR (XOR) operator, and
N is an integer greater than 1.

9. A memory device comprising:
a nonvolatile memory; and
a memory controller that:
a) attributes, for each of multiple error correction code (ECC) blocks, values to bits of the ECC block during a read operation of the nonvolatile memory;
b) identifies, among ECC blocks, errant ECC blocks that each has an errant value attributed to a bit of the ECC block;
c) determines whether an error exists in the j^{th} bit of one or more of the ECC blocks; and
d) performs operations (d1) through (d3) upon determining that the error exists in the j^{th} bit of one or more of the ECC blocks:
d1) retrieve an estimate of the voltage value stored by the nonvolatile memory cell corresponding to the j^{th} bit of each of the errant ECC blocks;
d2) identify, among the voltage value estimates retrieved in operation (d1), an ECC block whose corresponding voltage value estimate retrieved in operation (d1) is closest to the voltage value of a decision boundary for determining whether to assign a bit value of “0” or “1” to the j^{th} bit of the ECC blocks; and
d3) invert the value of the j^{th} bit of the ECC block identified in operation (d2).

10. The memory device of claim 9, wherein the memory controller further:
e) performs operations (c) and (d) for every value 1≦j≦m, where m is the number of bits within each of the ECC blocks.

11. The memory device of claim 10, wherein the memory controller further repeats operations (b) through (e) until fewer than two errant blocks are identified in operation (b) or the number of errant blocks identified in operation (b) does not decrease in successive repetitions of operations (b) through (e).

12. The memory device of claim 9, wherein the memory controller applies a cyclic redundancy check (CRC) code to each ECC block to identify, among the ECC blocks, the errant ECC blocks that have an errant value attributed to a bit of the ECC block.

13. The memory device of claim 12, wherein the memory controller performs Bose-Chaudhuri-Hocquenghem (BCH) decoding on each ECC block prior to applying the CRC code to each ECC block.

14. The memory device of claim 9, wherein:
the ECC blocks comprise Y₁ . . . Y_{N} ECC blocks of data encoded with a Bose-Chaudhuri-Hocquenghem (BCH) code and a Y_{N+1} parity block in which Y_{N+1}=Y₁⊕Y₂ ⊕ . . . ⊕Y_{N}, where ⊕ is an exclusive-OR (XOR) operator, and
N is an integer greater than 1.

15. A non-transitory computer readable medium storing instructions that when executed by a processor cause the processor to execute a method of correcting a value errantly attributed to a bit of an error correction code (ECC) block during a read operation of a nonvolatile memory, the method comprising:
a) identifying, among ECC blocks, errant ECC blocks that each has an errant value attributed to a bit of the ECC block;
b) determining whether an error exists in the j^{th} bit of one or more of the ECC blocks; and
c) performing operations (c1) through (c3) upon determining that an error exists in the j^{th} bit of one or more of the ECC blocks:
c1) retrieving an estimate of the voltage value stored by the nonvolatile memory cell corresponding to the j^{th} bit of each of the errant ECC blocks;
c2) identifying, among the voltage value estimates retrieved in operation (c1), an ECC block whose corresponding voltage value estimate retrieved in operation (c1) is closest to the voltage value of a decision boundary for determining whether to assign a bit value of “0” or “1” to the j^{th} bit of the ECC blocks; and
c3) inverting the value of the j^{th} bit of the ECC block identified in operation (c2).

16. The medium of claim 15, wherein the method further comprises:
d) performing operations (b) and (c) for every value 1≦j≦m, where m is the number of bits within each of the ECC blocks.

17. The medium of claim 16, wherein the method further comprises repeating operations (a) through (d) until fewer than two errant blocks are identified in operation (a) or the number of errant blocks identified in operation (a) does not decrease in successive repetitions of operations (a) through (d).

18. The medium of claim 15, wherein the method further comprises applying a cyclic redundancy check (CRC) code to each ECC block to identify, among the ECC blocks, the errant ECC blocks that have an errant value attributed to a bit of the ECC block.

19. The medium of claim 18, wherein the method further comprises performing Bose-Chaudhuri-Hocquenghem (BCH) decoding on each ECC block prior to applying the CRC code to each ECC block.

20. The medium of claim 13, wherein:
the ECC blocks comprise Y₁ . . . Y_{N} ECC blocks of data encoded with a Bose-Chaudhuri-Hocquenghem (BCH) code and a Y_{N+1} parity block in which Y_{N+1}=Y₁ ⊕Y₂ ⊕ . . . ⊕Y_{N}, where ⊕ is an exclusive-OR (XOR) operator, and
N is an integer greater than 1.
